(19) United States
(12) Patent Application Publication
(10) Pub. No.: US 2014/0209367 A1
(43) Pub. Date: Jul. 31, 2014

(54) WIRING BOARD

(71) Applicants: Jun Sakai, Tokyo (JP); Koichiro Nakase, Tokyo (JP)

(72) Inventors: Jun Sakai, Tokyo (JP); Koichiro Nakase, Tokyo (JP)

(73) Assignee: NEC CORPORATION, Tokyo (JP)

(21) Appl. No.: 14/342,019

(22) PCT Filed: Sep. 6, 2012
(86) PCT No.: PCT/JP2012/073388

§ 371 Date: Feb. 28, 2014

(30) Foreign Application Priority Data
Sep. 9, 2011 (JP) 2011-196934

(51) Int. Cl. H05K 1/02

(52) U.S. Cl. CPC H05K 1/0233
USPC 174/260; 174/266

(57) ABSTRACT

It is impossible to make a wiring board for noise suppression thinner, therefore, a wiring board according to an exemplary aspect of the invention includes a first wiring layer, an intermediate layer, and a second wiring layer; wherein the second wiring layer, the intermediate layer, and the first wiring layer are stacked in this order; the first wiring layer comprises a first wiring and a second wiring separated from the first wiring; the intermediate layer comprises a first via and a second via; the second wiring layer comprises a third wiring and a non-wiring portion where wirings are not formed; the first wiring is separated from the third wiring; the first via and the second via electrically connect the second wiring to the third wiring respectively; the non-wiring portion is located at a portion corresponding to an area between the first via and the second via; and the first wiring and the second wiring cross over the non-wiring portion.

### TECHNICAL FIELD

The present invention relates to a wiring board.

### BACKGROUND ART

In an electronic device where a plurality of semiconductor chips are mounted on a wiring board, the semiconductor chips and wirings electrically connecting to the semiconductor chips generate noise. As the noise affects the other semiconductor chips, these semiconductor chips may malfunction. In order to prevent such malfunction from arising, technologies for suppressing the noise have been developed.

FIG. 31 in Patent Literature 1 discloses a power supply noise suppression filter. The power supply noise suppression filter is composed of a parallel-plate waveguide type EBG (Electromagnetic Band Gap) device. It is disclosed that the parallel-plate waveguide type EBG device is made up of three conductor layers of a first conductor plane, a second conductor plane and, a conductor layer between the first conductor plane and the second conductor plane.

Patent Literature 1: WO2009/082003

### DISCLOSURE OF INVENTION

### Problem to be Solved by the Invention

The power supply noise suppression filter in Patent Literature 1 mentioned above is a wiring board made up of at least three wiring layers of the first conductor plane, the second conductor plane, and the conductor layer between the first conductor plane and the second conductor plane. Accordingly, since a wiring board for noise suppression requires at least three wiring layers, there has been a problem that it is impossible to make it thinner.

The object of the present invention is to provide a wiring board which can solve the above-mentioned problem that it is impossible to make a wiring board for noise suppression thinner.

### Means for Solving a Problem

A wiring board according to an exemplary aspect of the invention includes a first wiring layer, an intermediate layer, and a second wiring layer; wherein the second wiring layer, the intermediate layer, and the first wiring layer are stacked in this order; the first wiring layer comprises a first wiring and a second wiring separated from the first wiring; the intermediate layer comprises a first via and a second via; the second wiring layer comprises a third wiring and a non-wiring portion where wirings are not formed; the first wiring is separated from the third wiring; the first via and the second via electrically connect the second wiring to the third wiring respectively; the non-wiring portion is located at a portion corresponding to an area between the first via and the second via; and the first wiring and the second wiring cross over the non-wiring portion.

### Effect of the Invention

According to the wiring board of the present invention, it is possible to reduce the number of wiring layers in a wiring board for noise suppression and to make the wiring board thinner.

### BRIEF DESCRIPTION OF THE DRAWINGS

FIG. 1A is a developed view showing a wiring board in accordance with the first exemplary embodiment of the present invention.

FIG. 1B is a cross-sectional view showing a wiring board in accordance with the first exemplary embodiment of the present invention.

FIG. 2 is a diagram illustrating a transmission circuit model for a wiring board in accordance with the first exemplary embodiment of the present invention.

FIG. 3A is a developed view showing a wiring board in accordance with the second exemplary embodiment of the present invention.

FIG. 3B is a cross-sectional view showing a wiring board in accordance with the second exemplary embodiment of the present invention.

FIG. 4 is a perspective view showing a wiring board mounting integrated-circuits in accordance with exemplary example 1 of the present invention.

FIG. 5 is a diagram showing results of simulation for transmission characteristics of a wiring board mounting integrated-circuits in accordance with exemplary example 1 of the present invention.

FIG. 6A is a developed view showing a wiring board in accordance with the third exemplary embodiment of the present invention.

FIG. 6B is a cross-sectional view showing a wiring board in accordance with the third exemplary embodiment of the present invention.

FIG. 7A is a developed view showing a wiring board in accordance with the fourth exemplary embodiment of the present invention.

FIG. 7B is a cross-sectional view showing a wiring board in accordance with the fourth exemplary embodiment of the present invention.

FIG. 8 is a diagram illustrating a transmission circuit model for a wiring board in accordance with the fourth exemplary embodiment of the present invention.

FIG. 9 is a diagram showing results of simulation for transmission characteristics of a wiring board in accordance with the fourth exemplary embodiment of the present invention.

FIG. 10A is a developed view showing a wiring board in accordance with the fifth exemplary embodiment of the present invention.

FIG. 10B is a cross-sectional view showing a wiring board in accordance with the fifth exemplary embodiment of the present invention.

FIG. 11A is a developed view showing a wiring board in accordance with the fifth exemplary embodiment of the present invention.

FIG. 11B is a cross-sectional view showing a wiring board in accordance with the fifth exemplary embodiment of the present invention.

FIG. 12A is a developed view showing a wiring board in accordance with the sixth exemplary embodiment of the present invention.

FIG. 12B is a cross-sectional view showing a wiring board in accordance with the sixth exemplary embodiment of the present invention.

FIG. 13A is a developed view showing a wiring board in accordance with the sixth exemplary embodiment of the present invention.

FIG. 13B is a cross-sectional view showing a wiring board in accordance with the sixth exemplary embodiment of the present invention.

FIG. 14A is a developed view showing a wiring board in accordance with the seventh exemplary embodiment of the present invention.

FIG. 14B is a cross-sectional view showing a wiring board in accordance with the seventh exemplary embodiment of the present invention.

FIG. 15A is a developed view showing a wiring board in accordance with the seventh exemplary embodiment of the present invention.

FIG. 15B is a cross-sectional view showing a wiring board in accordance with the seventh exemplary embodiment of the present invention.

FIG. 16A is a developed view showing a wiring board in accordance with the eighth exemplary embodiment of the present invention.

FIG. 16B is a cross-sectional view showing a wiring board in accordance with the eighth exemplary embodiment of the present invention.

FIG. 17 is a diagram illustrating a transmission circuit model for a wiring board in accordance with the eighth exemplary embodiment of the present invention.

FIG. 18A is a developed view showing a wiring board in accordance with the ninth exemplary embodiment of the present invention.

FIG. 18B is a cross-sectional view showing a wiring board in accordance with the ninth exemplary embodiment of the present invention.

FIG. 19 is a diagram illustrating a transmission circuit model for a wiring board in accordance with the ninth exemplary embodiment of the present invention.

FIG. 20A is a developed view showing a wiring board in accordance with the tenth exemplary embodiment of the present invention.

FIG. 20B is a cross-sectional view showing a wiring board in accordance with the tenth exemplary embodiment of the present invention.

### DESCRIPTION OF EMBODIMENTS

### The First Exemplary Embodiment

(A Structure of a Wiring Board)

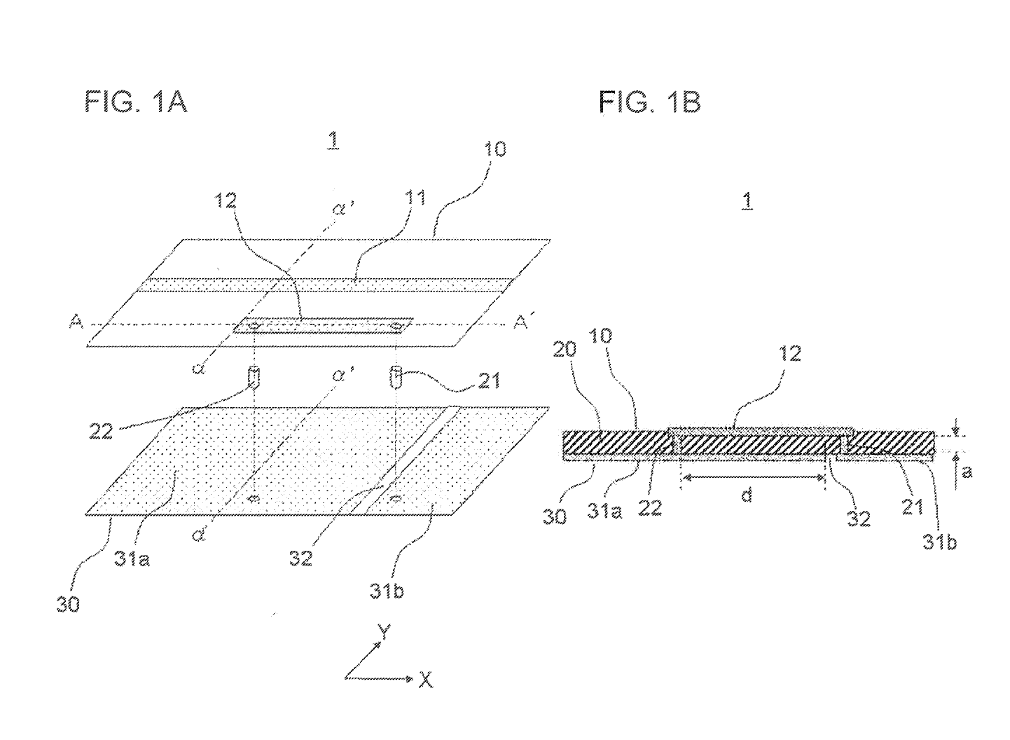

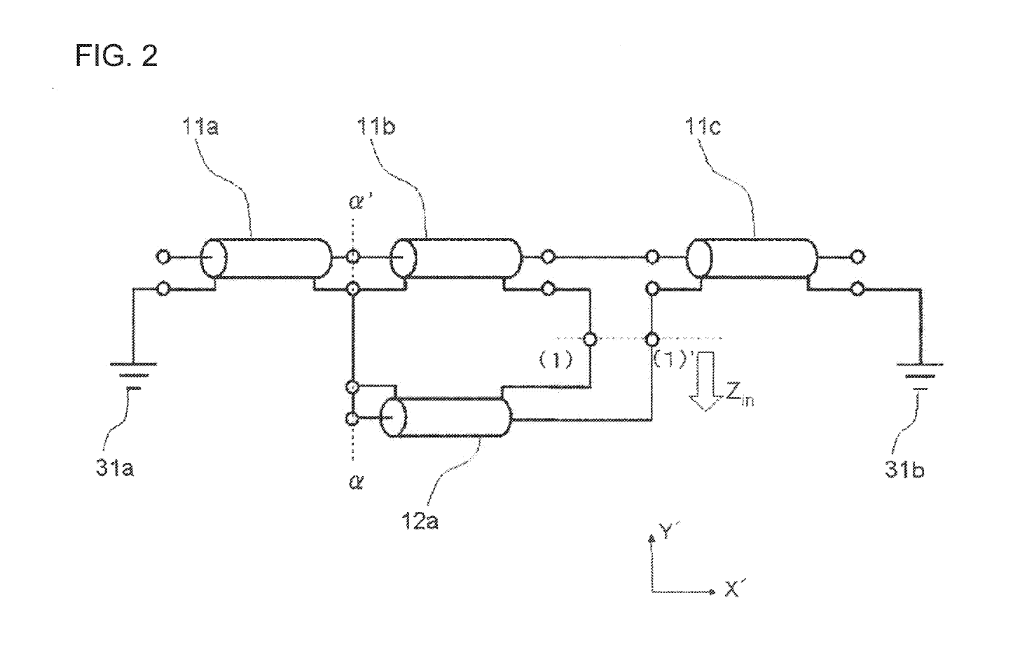

A wiring board in accordance with the first exemplary embodiment will be described referring to FIGS. 1A, 1B, 2A, and 2B.

FIGS. 1A and 1B are diagrams illustrating a wiring board 1. FIG. 1A is a developed view of the wiring board 1, and FIG. 1B is a cross-sectional view taken along the line A-A′ of FIG. 1A. In FIG. 1A, the positive direction of the X-axis is defined as the right direction, and the negative direction of the X-axis as the left direction. In diagrams other than FIG. 1A in which X-axis and Y-axis are illustrated, the left and right directions are also defined as is the case with FIG. 1A.

The wiring board 1 includes a first wiring layer 10, an intermediate layer 20, and a second wiring layer 30, which are stacked in order of the second wiring layer 30, the intermediate layer 20, and the first wiring layer 10.

The first wiring layer 10 includes a first wiring 11 and a second wiring 12 separated from the first wiring 11.

The intermediate layer 20 includes a first via 21 and a second via 22.

The second wiring layer 30 includes third wirings 31a and 31b, and a non-wiring portion 32 where the wirings are not formed.

The first wiring 11 is separated from the third wirings 31a and 31b. The first via 21 and the second via 22 electrically connect the second wiring 12 to the third wirings 31a and 31b, respectively. The non-wiring portion 32 is located at a portion corresponding to the area between the first via 21 and the second via 22. The first wiring 11 and the second wiring 12 cross over the non-wiring portion 32.

The third wirings 31a and 31b are separated by the non-wiring portion 32.

A printed-wiring board, a ceramic wiring board, and the like are used as the wiring board 1.

The wiring board 1 is approximately-rectangular, and an L shape, a circular form, and a doughnut shape, and the like are also available.

Here, the wiring board 1 is a two-layer wiring board including the first wiring layer 10 and the second wiring layer 30. It is also acceptable to apply the structure of the wiring board 1 to two layers among the wiring layers in a wiring board including more than three wiring layers.

Next, the structures of the first wiring layer 10, the intermediate layer 20, and the second wiring layer 30 will be described.

The first wiring layer 10 is approximately-rectangular, and an L shape, a circular form, and a doughnut shape, and the like are also available. The first wiring 11 and the second wiring 12 are approximately-rectangular, and a tapered shape and the like are also available. The first wiring 11 is approximately parallel to the second wiring 12, and can also be diagonal. The first wiring 11 reaches both ends of the first wiring layer 10 in a longitudinal direction. It is not necessarily, however, to reach the both ends. Although the second wiring 12 is shorter than the first wiring 11 in a longitudinal direction, it can be longer. Though the ends of the second wiring 12 in a longitudinal direction are located inside the ends of the wiring layer 10, it can reach the end.

The intermediate layer 20 is approximately-rectangular, and an L shape, a circular form, and a doughnut shape, and the like are also available. The first via 21 and the second via 22 are cylindrical, and they can also be rectangular parallelepipeds and the like.

The second wiring layer 30 is approximately-rectangular, and an L shape, a circular form, and a doughnut shape, and the like are also available. The non-wiring portion 32 is an approximately-rectangular shape whose side in the Y-axis direction is longer than that in the X-axis direction, and it is also acceptable to be longer in the X-axis direction or a circular shape and the like. The third wirings 31a and 31b are separated in the X-axis direction by the non-wiring portion 32. The third wirings 31a and 31b are approximately-rectangular, and a circular form and the like are also available. The third wiring 31a is located on the left side of the non-wiring portion 32, and the third wiring 31b is located on the right side of the non-wiring portion 32.

With regard to the first via 21 and the second via 22, one base is electrically connected to the second wiring 12. The other base of the first via 21 is electrically connected to the third wiring 31b, and the other base of the second via 22 is electrically connected to the third wiring 31a.

Next, a description will be given of materials of the first wiring layer 10, the intermediate layer 20, and the second wiring layer 30.

If the wiring board 1 is a printed-wiring board, the material of the first wiring 11 and the second wiring 12 in the first wiring layer 10 is copper. The material of the first via 21 and the second via 22 in the intermediate layer 20 is copper. The material in areas around the first via 21 and the second via 22 is any one of epoxy, polyimide, fluorine resin, phenol resin, and polyphenylene ether resin. The material of the third wirings 31a and 31b in the second wiring layer 30 is copper.

The case where the wiring board 1 is a ceramic wiring board will be described. The material of the first wiring 11 and the second wiring 12 in the first wiring layer 10 is any one of silver and silver-palladium. The material of the first via 21 and the second via 22 in the intermediate layer 20 is any one of silver and silver-palladium. The material in areas around the first via 21 and the second via 22 is any one of alumina ceramic and glass ceramic. The material of the third wirings 31a and 31b in the second wiring layer 30 is any one of silver and silver-palladium.

The case where the wiring board 1 is neither a printed wiring board nor a ceramic wiring board will be described. The material of the first wiring 11 and the second wiring 12 in the first wiring layer 10 is any one of gold, copper, aluminum and the like. The material of the first via 21 and the second via 22 in the intermediate layer 20 is any one of gold, copper, aluminum and the like. The material in areas around the first via 21 and the second via 22 is any one of glass, silicon, composite material and the like. The material of the third wirings 31a and 31b in the second wiring layer 30 is any one of gold, copper, aluminum and the like.

(The Function of the Wiring Board 1)

The function of the wiring board 1 will be described with reference to FIG. 2.

FIG. 2 is an equivalent circuit of the wiring board 1. The equivalent circuit includes transmission circuit models 11a, 11b, and 11c for the first wiring and a transmission circuit model 12a for the second wiring. Here, the first wiring 11 functions as a signal wiring and the third wiring functions as a ground wiring.

In FIG. 2, the positive direction of the X′-axis is defined as the right direction, the negative direction of the X′-axis as the left direction, the positive direction of the Y′-axis as the upward direction, and the negative direction of the Y′-axis as the downward direction. In figures other than FIG. 2 in which X′-axis and Y′-axis are illustrated, the left, right, upward, and downward directions are also defined as is the case with FIG. 2.

The transmission circuit models 11a, 11b, and 11c of the first wiring and the transmission circuit model 12a of the second wiring are represented by cylindrical elements. A terminal extending from the center of the cylindrical element to right and left represents a signal, which will be described as a signal terminal below. The terminal extending from the top or the bottom of the cylindrical element represents a reference, which will be described as a reference terminal below. In FIG. 2, lines connecting one cylindrical element to another represent the connection between the transmission circuit models 11a, 11b, 11c of the first wiring, and the transmission circuit model 12a of the second wiring, which do not have an electrical meaning such as wiring length.

The transmission circuit model 11a of the first wiring represents a microstripline composed of the portion of the first wiring 11 located on the left side of the dotted line a-a′ and the third wiring 31a in FIG. 1.

Similarly, the transmission circuit model 11b of the first wiring represents a microstripline composed of the third wiring 31a and the portion of the first wiring 11 located between the dotted line a-a′ and the non-wiring portion 32 in FIG. 1.

The transmission circuit model 11c of the first wiring represents a microstripline in FIG. 1 composed of the portion of the first wiring 11 located on the right side of the non-wiring portion 32 and the third wiring 31b in FIG. 1.

The transmission circuit model 12a of the second wiring represents a microstripline composed of the second wiring 12 and the third wirings 31a and 31b.

With regard to the transmission circuit model 11a of the first wiring, the left-hand reference terminal is connected to the ground, the right-hand signal terminal is connected to the left-hand signal terminal of the transmission circuit model 11b of the first wiring, and the right-hand reference terminal is connected to the left-hand reference terminal of the transmission circuit model 11b of the first wiring.

With regard to the transmission circuit model 11b of the first wiring, the right-hand signal terminal is connected to the left-hand signal terminal of the transmission circuit model 11c of the first wiring, and the right-hand reference terminal is connected to the right-hand reference terminal of the transmission circuit model 12a of the second wiring.

With regard to the transmission circuit model 11c of the first wiring, the right-hand reference terminal is connected to the ground.

Here, the transmission circuit model 12a of the second wiring is characterized by the configuration that the right-hand reference terminal is connected to the reference terminal of the transmission circuit model 11b of the first wiring, the right-hand signal terminal is connected to the reference terminal of 11c, and two left-hand terminals are short-circuited.

With regard to the transmission circuit model 12a of the second wiring, two left-hand terminals are connected to the right-hand reference terminal of the transmission circuit model 11a of the first wiring.

In FIG. 2, an input impedance Zᵢₙ is defined as a value viewed from the right-hand signal terminal and the reference terminal in the transmission circuit model 12a of the second wiring (see the dotted line (1)-(1)′) toward the short-circuited portion on the left side in the transmission circuit model 12a of the second wiring.

The input impedance Zᵢₙ is expressed by the following formula 1 and formula 2. Here, j represents the imaginary unit, Z_{g} represents the characteristic impedance of the transmission circuit model 12a of the second wiring, β represents a phase constant, d represents the distance from the left end of the non-wiring portion 32 to the right end of the second via 22, and X represents the wavelength of electromagnetic wave.

$$\begin{matrix}{Z}_{in} = j {Z}_{g} tan β d & FORMULA 1 \\ {Z}_{in} = j {Z}_{g} tan \frac{π}{2} = ∞ & FORMULA 2\end{matrix}$$

The input impedance Zᵢₙ expressed by formula 1 becomes equal to that expressed by formula 2 and reaches an infinite value at the frequencies of an odd multiple of a frequency corresponding to d=λ/4.

The circuit composed of the second wiring 12 and the third wirings 31a and 31b, therefore, functions as a resonator at the frequencies mentioned above, and inhibits the propagation of a return current flowing through the third wirings 31a and 31b. In this way, it is possible for the wiring board 1 of the present exemplary embodiment to remove, as noise, signals with frequencies of an odd multiple of a frequency corresponding to d=λ/4 from among signals having propagated through the micro stripline composed of the first wiring 11 and the third wirings 31a and 31b.

It is possible to design d by using the following formula 3. Here, f represents a noise frequency, c represents the speed of light, and εᵣ represents the relative permittivity of the material around the first via 21 and the second via 22 in the intermediate layer 20.

$$d = \frac{λ}{4} = \frac{c}{4 \sqrt{{ɛ}_{r}} f} \qquad FORMULA 3$$

(The Method for Making the Wiring Board 1)

The method for making the wiring board 1 will be described. It is possible to make the wiring board 1 by means of a publicly known method for making a printed wiring board, a publicly known method for making a ceramic wiring board, and the like.

(The Effect of the Wiring Board 1)

Since the wiring board 1 to remove noise is composed of a two-layered wiring layer including the first wiring layer 10 and the second wiring layer 30, it is possible to make it thinner.

### The Second Exemplary Embodiment

(A Structure of a Wiring Board)

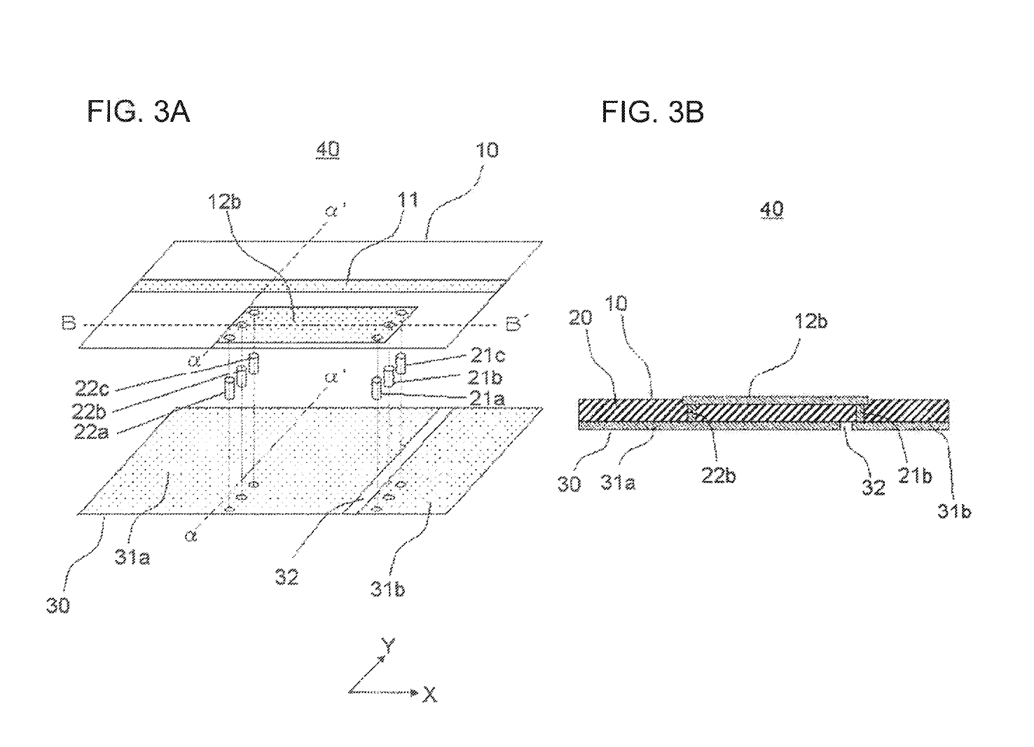

The second exemplary embodiment will be described referring to FIGS. 3A and 3B. FIGS. 3A and 3B are diagrams to illustrate a wiring board 40. Here, FIG. 3A is a developed view of the wiring board 40, and FIG. 3B is a cross-sectional view taken along the line B-B′ of FIG. 3A.

In the present exemplary embodiment, each configuration which has approximately the same function as that of the configuration in the first exemplary embodiment is given the same sign and its description is omitted.

In the present exemplary embodiment, the width of a second wiring 12b is made thicker than that of the second wiring 12 in the first exemplary embodiment. Here, the width means the length of the second wiring 12b in the Y-axis direction.

The intermediate layer 20 includes three first vias 21a, 21b and 21c and three second vias 22a, 22b and 22c.

With regard to the first vias 21a, 21b, 21c and the second vias 22a, 22b and 22c, one base is connected to the second wiring 12b. Each other base of the first vias 21a, 21b and 21c is electrically connected to a third wiring 31b, and each other base of the second vias 22a, 22b and 22c is electrically connected to a third wiring 31a.

(The Function of the Wiring Board 40)

It is possible also in the present exemplary embodiment to determine a frequency of noise to be removed by the same calculation method as that in the first exemplary embodiment, which does not depend on the width of the second wiring 12b.

(The Effect of the Wiring Board 40)

Since the wiring board 40 to remove noise is composed of a two-layered wiring layer including the first wiring layer 10 and the second wiring layer 30, it is possible to make it thinner.

Additionally, because the second wiring 12b is electrically connected to the third wiring 31b through the three first vias 21a, 21b and 21c, the connection becomes tight. Similarly, because the second wiring 12b is electrically connected to the third wiring 31a through the three second vias 22a, 22b and 22c, the connection becomes tight.

In addition, because the wiring board 40 includes three first vias 21a, 21b and 21c, they get electrically connected as long as at least one of the vias is connected, which improve the production yield. As is the case with the first via described above, the production yield of the wiring board 40 is improved by three second vias 22a, 22b and 22c.

### EXEMPLARY EXAMPLE 1

(A Structure of a Wiring Board Mounting Integrated-Circuits)

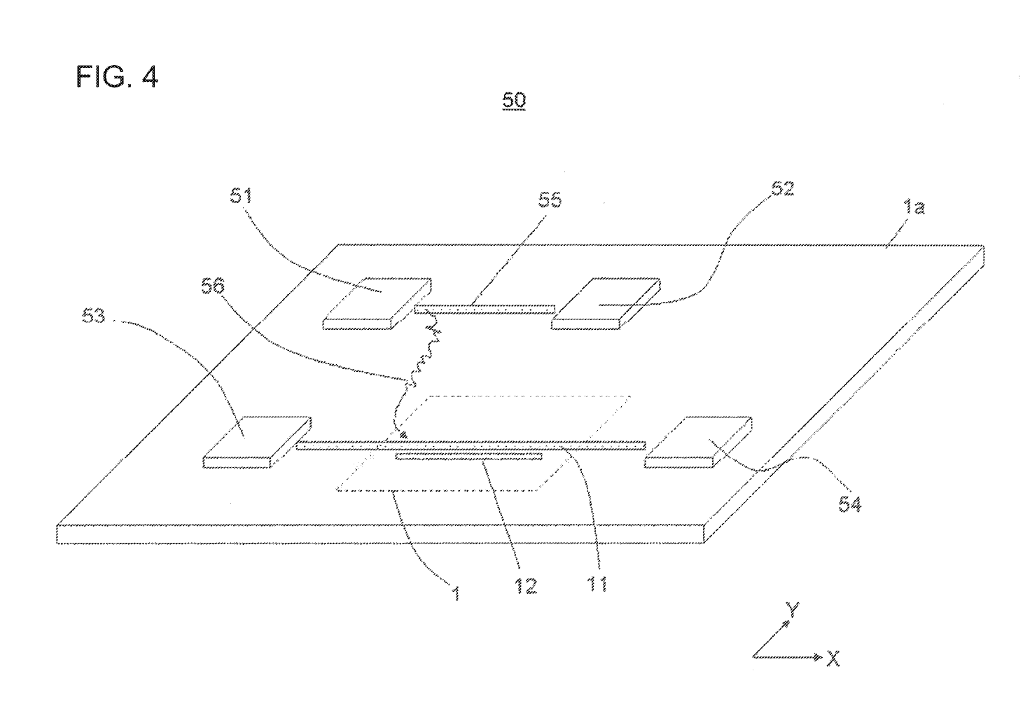

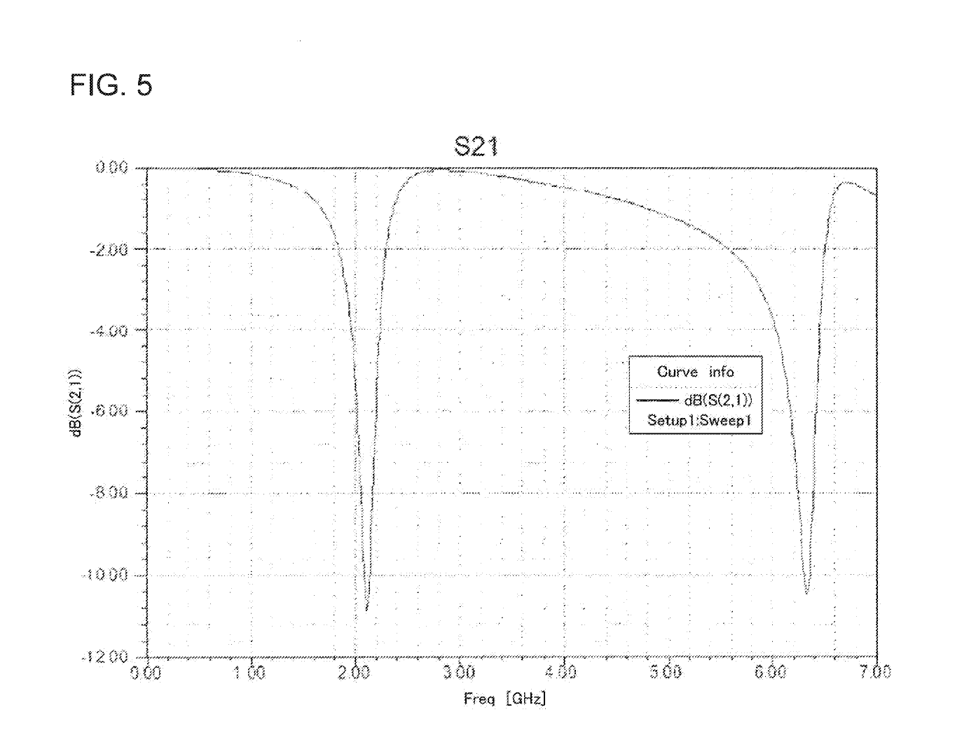

A description will be given of a wiring board mounting integrated-circuits 50 of exemplary example 1 referring to FIGS. 4 and 5. FIG. 4 is a perspective view to illustrate the wiring board mounting integrated-circuits 50.

In the wiring board mounting integrated-circuits 50, integrated circuits 51 to 54 are mounted on a wiring board la. The wiring board la includes a fourth wiring 55 between the integrated circuit 51 and the integrated circuit 52. The integrated circuit 51 is electrically connected to the integrated circuit 52 through the fourth wiring 55.

The wiring board la includes the structure of the wiring board 1 between the integrated circuit 53 and the integrated circuit 54. That is to say, between the integrated circuit 53 and the integrated circuit 54, the wiring board la includes the first wiring 11, the second wiring 12, the first via 21, the second via 22, the third wirings 31a and 31b, and the non-wiring portion 32. The third wirings 31a and 31b are separated from each other by the non-wiring portion 32. Even in the area of the wiring board la which is larger than the wiring board 1, the third wiring 31a is separated from the third wiring 31b. The integrated circuit 53 is electrically connected to one end of the first wiring 11, and the integrated circuit 54 is electrically connected to the other end of the first wiring 11. The integrated circuit 53 is electrically connected to the integrated circuit 54 through the first wiring 11. The integrated circuit 51, the integrated circuit 52, and the fourth wiring 55 are disposed close to the wiring board 1.

(An Operation of the Wiring Board Mounting Integrated-Circuits 50)

The integrated circuit 51 sends a clock signal having a frequency component of 2.1 GHz to the integrated circuit 52 through the fourth wiring 55. The integrated circuit 53 sends a digital signal of 500 Mbps (mega bit per second) to the integrated circuit 54 through the first wiring 11. A part of the clock signal transmitted through the fourth wiring 55 is coupled with the first wiring 11 as noise 56. Although the noise 56 arising from the fourth wiring 55 will be described here, there is a case where noise arising from the integrated circuit 51 becomes dominant.

With regard to the structure of the wiring board 1, the wiring board 1 includes the intermediate layer 20, and the relative permittivity (Eᵣ) of the material around the first via 21 and the second via 22 is equal to 4.4. The thickness a of the intermediate layer 20 shown in FIG. 1 is equal to 60 μm. The each thickness of the first wiring 11, the second wiring 12, and the third wirings 31a and 31b is equal to 20 μm. The width of the second wiring 12 is equal to 1 mm. The distance d from the left end of the non-wiring portion 32 to the right end of the second via 22 is equal to 17.3 mm. The length of the first wiring 11 is equal to 30 mm, and the length of the second wiring 12 is equal to 18 mm. Each of the distance from the left end of the second wiring 12 to the right end of the integrated circuit 53, and the distance from the right end of the second wiring 12 to the left end of the integrated circuit 54, is equal to 6 mm.

(Simulation Results of the Wiring Board Mounting Integrated-Circuits 50)

FIG. 5 is a graph showing results of the electromagnetic analysis on the transmission characteristics of the first wiring 11 by means of a three-dimensional electric field simulator.

The graph shows the insertion loss S21 among the S parameters of the first wiring 11, where the horizontal axis represents the frequency, and the vertical axis represents the loss. The insertion loss S21 represents the ratio of a signal reaching the integrated circuit 54 to a signal output from the integrated circuit 53. The insertion loss S21 becomes smaller significantly at the resonant frequencies of 2.1 GHz and 6.3 GHz which is three times the frequency of 2.1 GHz, but it is nearly equal to 0 dB at other frequencies.

The results indicate that the structure of the wiring board 1 functions as a band rejection filter by which the signal propagation is inhibited due to the strong attenuation of a signal with a specific frequency and signals with the other frequencies are transmitted.

(The Effect of the Wiring Board Mounting Integrated-Circuits 50)

Accordingly, the 500 Mbps signal output from the integrated circuit 53 reaches the integrated circuit 54 without a loss, and the noise 56 with 2.1 GHz arriving from the integrated circuit 51 is removed. That is to say, it is possible for the integrated circuit 53 to transmit a signal to the integrated circuit 54 successfully.

### The Third Exemplary Embodiment

(A Structure of a Wiring Board)

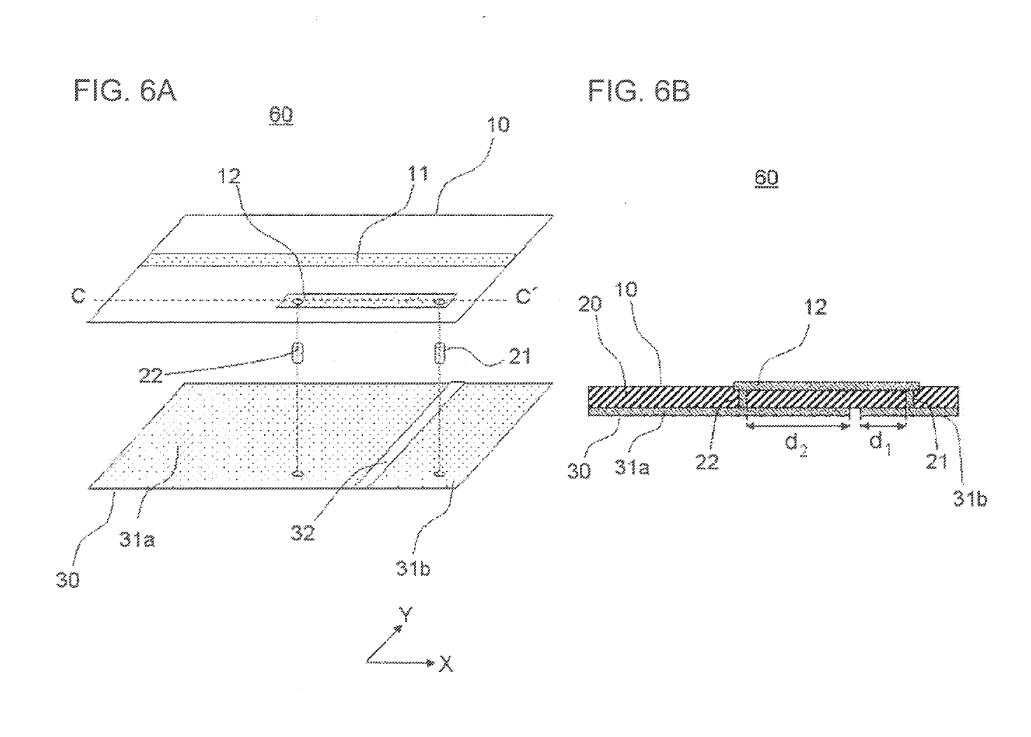

A wiring board in accordance with the third exemplary embodiment will be described referring to FIGS. 6A and 6B. Here, FIG. 6A is a developed view of a wiring board 60, and FIG. 6B is a cross-sectional view taken along the line C-C′ of FIG. 6A.

In the present exemplary embodiment, each configuration which has approximately the same function as that of the configuration in the first and second exemplary embodiments is given the same sign and its description is omitted.

The feature of the present exemplary embodiment is that the first via 21 and the second via 22 are disposed separately from the non-wiring portion 32 to the extent that the noise is attenuated at two frequencies described below. In this structure, it is possible to form a resonator on each side of the non-wiring portion 32 and to attenuate the noise at arbitrary two different frequencies.

In FIG. 6B, the sign of d₁ represents the distance from the left end of the first via 21 to the right end of the non-wiring portion 32. The sign of d₂ represents the distance from the right end of the second via 22 to the left end of the non-wiring portion 32.

(The Function of the Wiring Board 60)

The function of the wiring board 60 will be described. A microstrip wiring with the length d₁ is formed on the right side of the non-wiring portion 32 by the second wiring 12 and the third wiring 31b, and it attenuates the noise at the frequency when d₁ becomes equal to λ₁/4 (d₁=λ₁/4). Similarly, a micro strip wiring with the length d₂ is formed on the left side of the non-wiring portion 32 by the second wiring 12 and the third wiring 31a, and it attenuates the noise at the frequency when d₂ becomes equal to λ₂/4 (d₂=λ₂/4).

(The Effect of the Wiring Board 60)

Since the wiring board 60 to remove noise is composed of a two-layered wiring layer including the first wiring layer 10 and the second wiring layer 30, it is possible to make it thinner.

Additionally, it is possible for the wiring board 60 to remove noise at arbitrary two different frequencies.

### The Fourth Exemplary Embodiment

(A Structure of a Wiring Board)

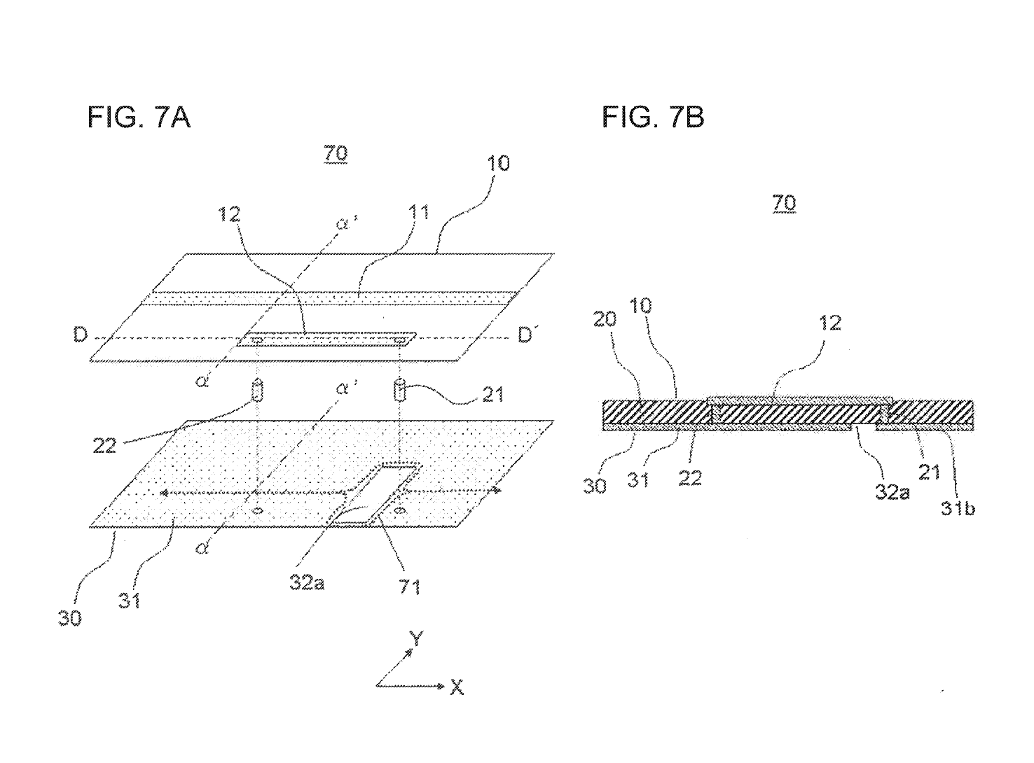

A wiring board in accordance with the fourth exemplary embodiment will be described referring to FIGS. 7A, 7B, 8, and 9. Here, FIG. 7A is a developed view of a wiring board 70, and FIG. 7B is a cross-sectional view taken along the line D-D′ of FIG. 7A.

In the present exemplary embodiment, each configuration which has approximately the same function as that of the configuration in the first to third exemplary embodiments is given the same sign and its description is omitted.

The feature of the present exemplary embodiment is that a non-wiring portion 32a is located inside the third wiring 31.

The non-wiring portion 32a is approximately-rectangular, a circular shape and the like are also available, and there is the third wiring 31 around it. The first via 21 electrically connects the second wiring 12 to the third wiring 31 on the right side of the non-wiring portion 32a. The second via 22 electrically connects the second wiring 12 to the third wiring 31 on the left side of the non-wiring portion 32a.

(The Function of the Wiring Board 70)

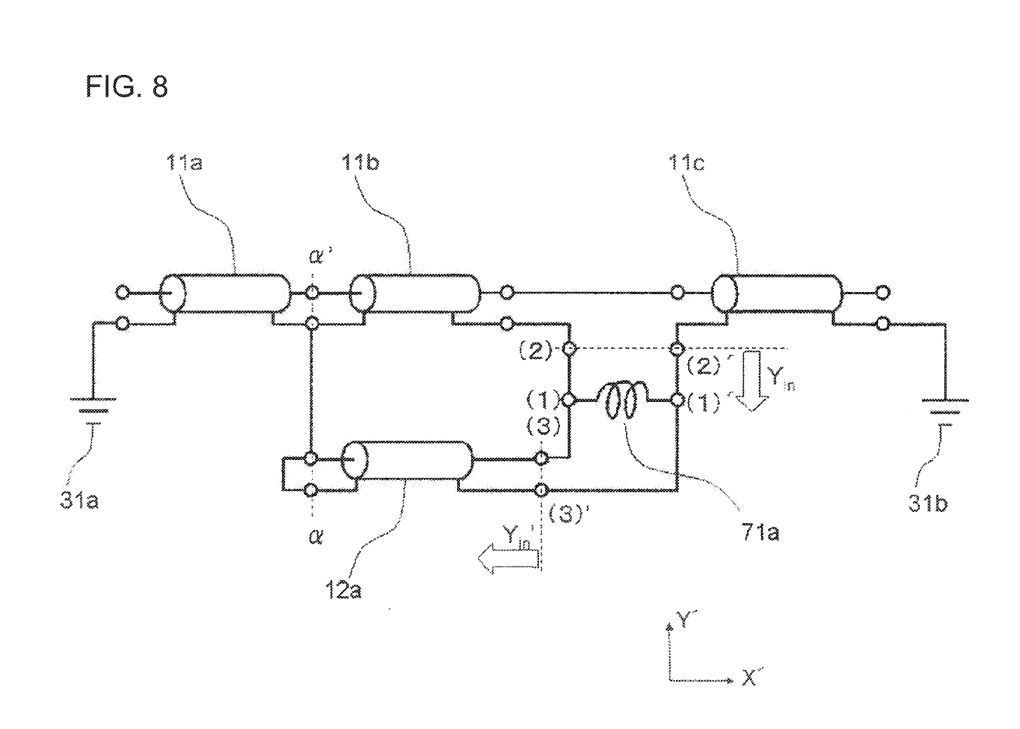

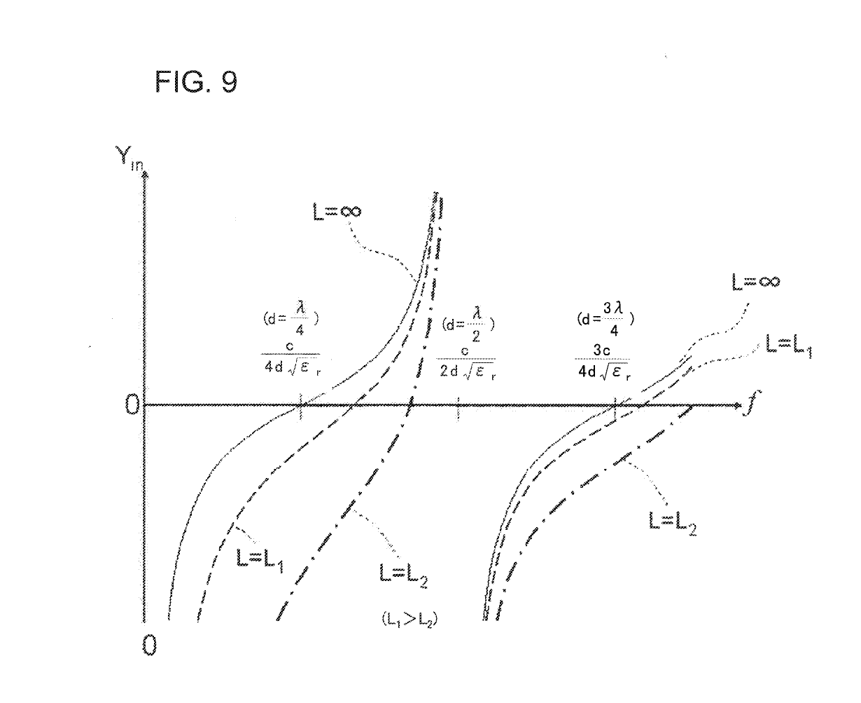

The function of the wiring board 70 will be described referring to FIGS. 8 and 9.

FIG. 8 shows an equivalent circuit of the wiring board 70. FIG. 8 differs from FIG. 2 by the presence of an inductor 71a. The inductor 71a connects the right-hand reference terminal of the transmission circuit model 11b of the first wiring to the left-hand reference terminal of the transmission circuit model 11c of the first wiring, and it represents an electric current bypassing the periphery of the non-wiring portion 32a.

In FIG. 8, an input admittance Yᵢₙ is defined as an admittance viewed from the right-hand reference terminal in the transmission circuit model 11b of the first wiring and the left-hand reference terminal in the transmission circuit model 11c of the first wiring (see (2)-(2)′ in FIG. 8) toward the transmission circuit model 12a of the second wiring.

An input admittance Y′ᵢₙ is defined as an admittance viewed from the right-hand signal terminal and the reference terminal in the transmission circuit model 12a of the second wiring (see (3)-(3)′ in FIG. 8) toward the transmission circuit model 12a of the second wiring. Y′ᵢₙ is expressed by the following formula 4. Here, Z_{g} represents a characteristic impedance of the micro stripline composed of the second wiring 12 and the third wiring 31, represents a propagation constant, and d represents the distance of the left end of the non-wiring portion 32a to the right end of the second via 22.

$${Y}_{in}^{′} = - \frac{j}{{Z}_{g} tan β d} \qquad FORMULA 4$$

The input admittance Y′ᵢₙ becomes zero at a frequency when d becomes equal to λ/4 (d=λ/4) because a tangent of βd becomes infinite (tan(βd)=∞). That is to say, the input impedance corresponding to the input admittance Y′ᵢₙ becomes infinite.

The input admittance Yᵢₙ is expressed by the following formula 5 with L representing an inductance value of the inductor 71a.

$${Y}_{in} = {Y}_{in}^{′} + \frac{1}{j ω L} = - j ( \frac{1}{{Z}_{g} tan β d} + \frac{1}{ω L} ) \qquad FORMULA 5$$

When the input admittance Yin is equal to zero, a signal propagating through the transmission circuit models 11a, 11b, and 11c of the first wiring is attenuated.

A description will be given of the relationship between the input admittance Yᵢₙ and the inductance 71a due to an electric current bypassing the periphery of the non-wiring portion 32a referring to FIG. 9. FIG. 9 shows frequency characteristics of the input admittance Yᵢₙ.

The structure of the first exemplary embodiment does not include a bypassing current path, and accordingly it corresponds to the condition of L=∞. The input admittance Yᵢₙ in that case is represented by data expressed in a solid line on the extreme left among graphs in FIG. 9, and it becomes equal to zero at a frequency of f=c/(4dεᵣ^{0.5}) corresponding to d=λ/4.

In the present exemplary embodiment, L has a finite value because of there being a bypassing current path, and the input admittance Yᵢₙ moves to the bottom right of the graph as the value of L decreases. In FIG. 9, L1 is larger than L2 (L1>L2), and if L is equal to L₁, the admittance Yᵢₙ is represented by data expressed in a dashed line on the second graph from the left in FIG. 9. Similarly, if L is equal to L₂, the admittance Yᵢₙ is represented by data expressed in a dashed-dotted line on the third graph from the left in FIG. 9. The values of the admittance Yᵢₙ for the case of L=L₂ is moved closer to the bottom right of the graph than those for the case of L=L₁.

Here, the data for L=∞, L₁, and L₂ are repeated with a period of c/(2dε^{0.5}). In the graphs of FIG. 9, the first to third data from the left represent those of the first cycle, and the fourth to sixth data represent those of the second cycle.

Signal propagation is suppressed when the input admittance Yᵢₙ becomes equal to zero. That is to say, a frequency at which signal propagation is suppressed moves to the higher frequency region as L decreases. L becomes smaller if the circumference of the non-wiring portion 32a becomes shorter. When L approaches zero sufficiently, a frequency at which the input admittance Yᵢₙ is equal to zero becomes equal to c/(2dεᵣ^{0.5}), and the frequency does not move to any higher frequency than the value.

(The Effect of the Wiring Board 70)

Since the wiring board 70 to remove noise is composed of a two-layered wiring layer including the first wiring layer 10 and the second wiring layer 30, it is possible to make it thinner.

Additionally, in the wiring board 70, by disposing the non-wiring portion 32a inside the third wiring 31 for the electric current to bypass it, it is possible to move a frequency at which the noise is attenuated to the higher frequency region compared to the first exemplary embodiment.

### The Fifth Exemplary Embodiment

(A Structure of a Wiring Board)

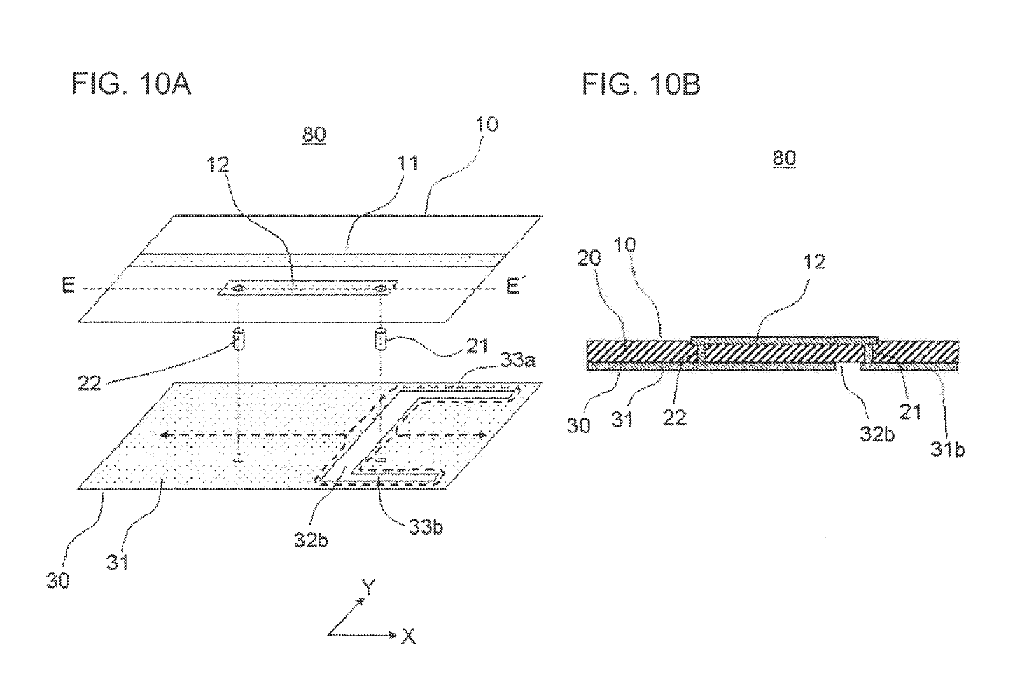

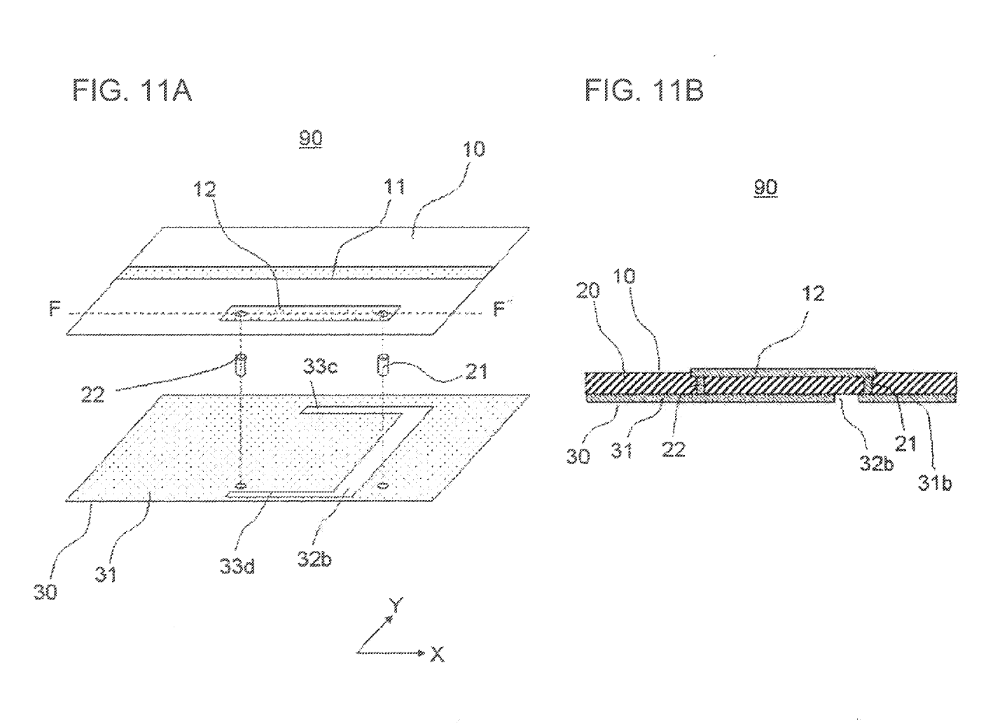

A wiring board of the fifth exemplary embodiment will be described referring to FIGS. 10A, 10B, 11A, and 11B. Here, FIG. 10A is a developed view of the wiring board 80, and FIG. 10B is a cross-sectional view taken along the line E-E′ of FIG. 10A. FIG. 11A is a developed view of the wiring board 90, and FIG. 11B is a cross-sectional view taken along the line F-F′ of FIG. 11A.

In the present exemplary embodiment, each configuration which has approximately the same function as that of the configuration in the first to fourth exemplary embodiments is given the same sign and its description is omitted.

In the present exemplary embodiment, the non-wiring portion 32b is located inside the third wiring 31 and is approximately-rectangular, and a circular shape and the like are also available. The non-wiring portion 32b includes openings 33a and 33b which extend approximately parallel to the first wiring 11 respectively from two ends at which the first wiring 11 and the second wiring 12 intersect the non-wiring portion 32b in the direction of traverse. It is also acceptable for the opening 33a to be inclined to the opening 33b. The openings 33a and 33b are approximately-rectangular, and a circular shape and the like are also available.

As shown in FIG. 10A, the non-wiring portion 32b includes the openings 33a and 33b which extend to the right from its two ends in the Y-axis direction.

Alternatively, as shown in FIG. 11A, it is also acceptable for openings 33c and 33d to extend leftward. FIG. 11A differs from FIG. 10A only in the direction in which the openings 33c and 33d extend.

(The Function of the Wiring Boards 80 and 90)

The function of the wiring boards 80 and 90 will be described below. An equivalent circuit in the present exemplary embodiment is shown in FIG. 8 similarly to the fourth exemplary embodiment. In the present exemplary embodiment, a return current flowing through the third wiring 31 largely bypasses the peripheries of the non-wiring portion 32b, the opening 33a, and the opening 33b as the path is shown by a dashed line in FIG. 10A. In the case of FIG. 11A, similarly, a return current flowing through the third wiring 31 largely bypasses the peripheries of the non-wiring portion 32b, the opening 33c, and the opening 33d.

An inductance value in the inductor 71a, therefore, becomes larger, and a frequency at which the noise is attenuated depending on the inductance value moves to the lower frequency side. Thus, by adding the openings 33a and 33b, or the openings 33c and 33d to the non-wiring portion 32b, it is possible to move a frequency to remove the noise toward the lower frequency side.

(The Effect of the Wiring Boards 80 and 90)

Since each of the wiring boards 80 and 90 to remove noise is composed of a two-layered wiring layer including the first wiring layer 10 and the second wiring layer 30, it is possible to make it thinner.

Additionally, in the wiring boards 80 and 90, by disposing the non-wiring portion 32b inside the third wiring 31 and adding the openings 33a and 33b, or the openings 33c and 33d to the non-wiring portion 32b, it is possible to move a frequency at which the noise is attenuated to the higher frequency region compared to the fourth exemplary embodiment.

### The Sixth Exemplary Embodiment

(A Structure of a Wiring Board)

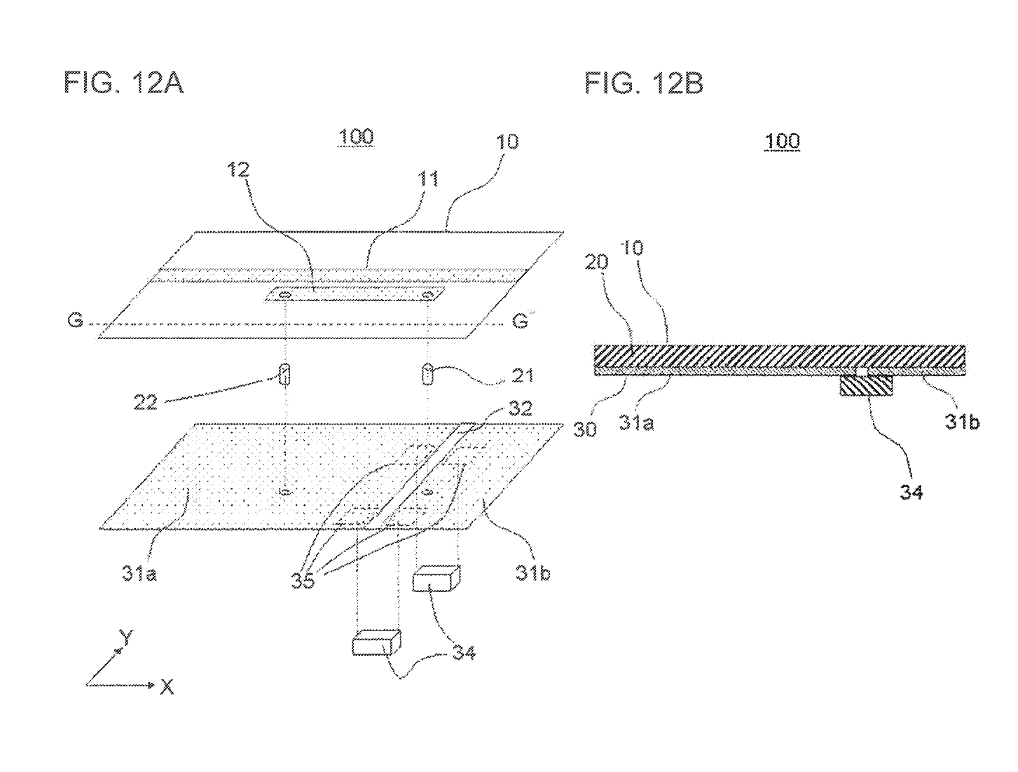

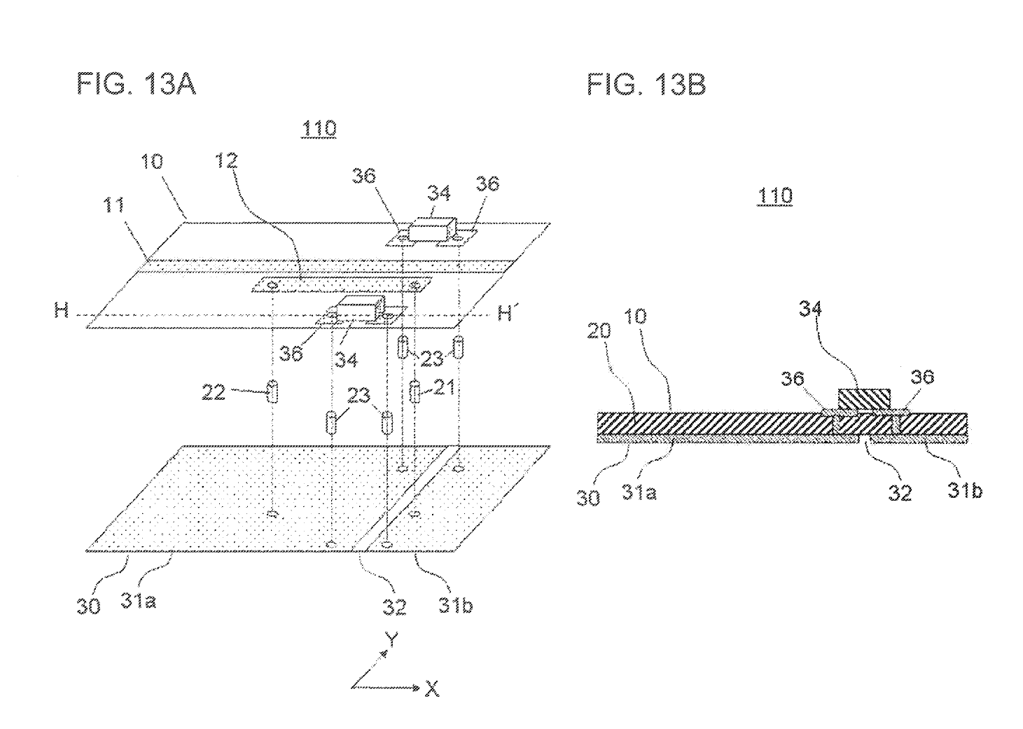

A wiring board in accordance with the sixth exemplary embodiment will be described referring to FIGS. 12A, 12B, 13A, and 13B. Here, FIG. 12A is a developed view of a wiring board 100, and FIG. 12B is a cross-sectional view taken along the line G-G′ of FIG. 12A. FIG. 13A is a developed view of a wiring board 110, and FIG. 13B is a cross-sectional view taken along the line H-H′ of FIG. 13A.

In the present exemplary embodiment, each configuration which has approximately the same function as that of the configuration in the first to fifth exemplary embodiments is given the same sign and its description is omitted.

In the present exemplary embodiment, first inductor chips 34 are included, and the separated third wirings 31a and 31b are electrically connected to each other by the first inductor chips 34.

As shown in FIGS. 12A and 12B, the third wirings 31a and 31b are separated from each other by the non-wiring portion 32, and the left side of the non-wiring portion 32 is the third wiring 31a, and the right side is the third wiring 31b. Each of the third wirings 31a and 31b has two pads 35 to mount the first inductor chips. Two first inductor chips 34 are mounted on the pads 35 to mount the first inductor chips. Although the example in which two first inductor chips 34 are mounted has been illustrated above, the number of the first inductor chips 34 is not limited to two, and it is also acceptable to mount one inductor chip or mount three or more inductor chips.

Alternatively, as shown in FIGS. 13A and 13B, the pads to mount the first inductor chips are located on the first wiring layer 10. The pads 36 to mount the first inductor chips are electrically connected to the third wirings 31a and 31b through third vias 23. The two first inductor chips 34 are mounted on the pads 36 to mount the first inductor chips.

(The Function of the Wiring Boards 100 and 110)

The function of the wiring boards 100 and 110 will be described. An equivalent circuit in the present exemplary embodiment is shown in FIG. 8 similarly to the fourth exemplary embodiment. The present exemplary embodiment differs from the third exemplary embodiment in that an element composing the inductor is not the electric current bypassing the third wiring 31 but the first inductor chips 34 mounted. L becomes a finite value due to the mounted first inductor chips 34, and a frequency at which the input admittance Yin becomes equal to zero moves to the higher frequency side as shown in FIG. 9.

(The Effect of the Wiring Boards 100 and 110)

Since the wiring boards 100 and 110 to remove noise is composed of a two-layered wiring layer including the first wiring layer 10 and the second wiring layer 30, it is possible to make it thinner.

Additionally, in the wiring boards 100 and 110, by means of the mounted first inductor chips 34, it is possible to move a frequency at which the noise is attenuated to the higher frequency side compared to the first exemplary embodiment.

In addition, since the mounted first inductor chips 34 pass direct current or low frequency signals, it is possible to strengthen the electrical connection between the third wiring 31a and the third wiring 31b.

### The Seventh Exemplary Embodiment

(A Structure of a Wiring Board)

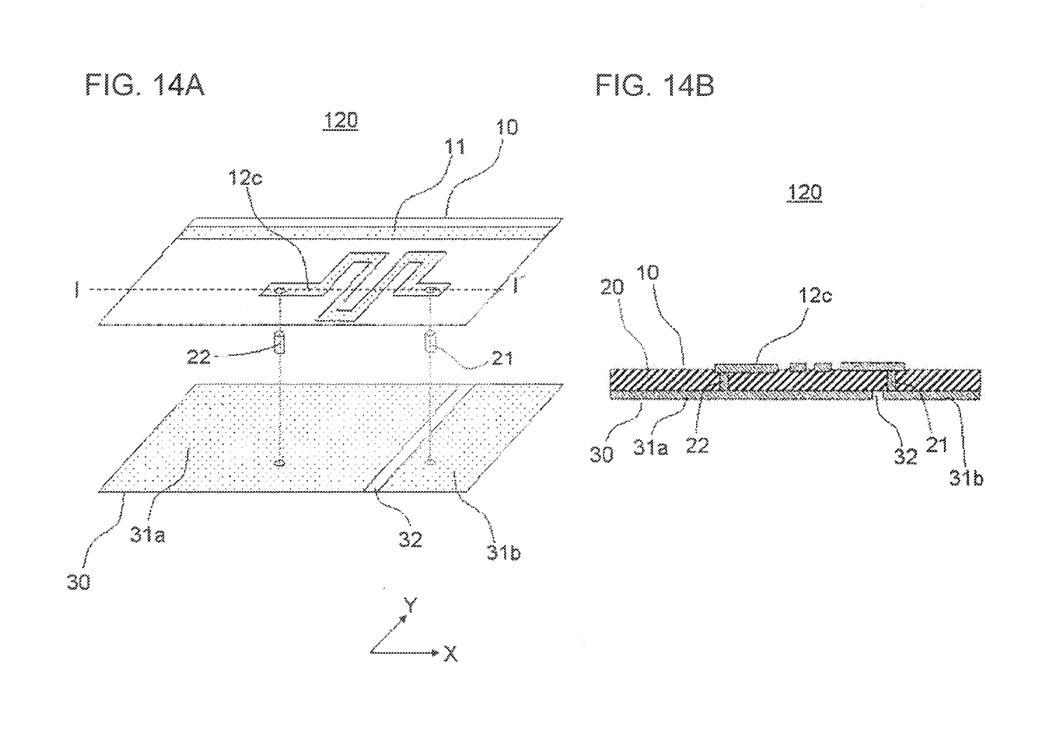

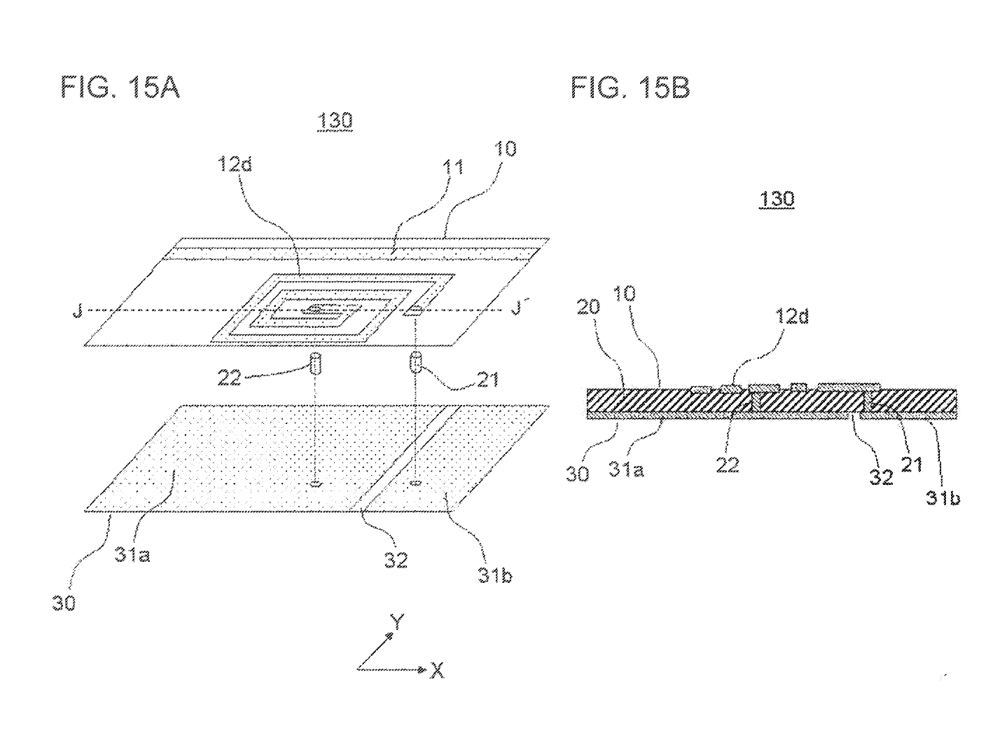

A wiring board of the seventh exemplary embodiment will be described referring to FIGS. 14A, 14B, 15A, and 15B. Here, FIG. 14A is a developed view of the wiring board 120, and FIG. 14B is a cross-sectional view taken along the line I-I′ of FIG. 14A. FIG. 15A is a developed view of the wiring board 130, and FIG. 15B is a cross-sectional view taken along the line J-J′ of FIG. 15A.

In the present exemplary embodiment, each configuration which has approximately the same functions as that of the configuration in the first to sixth exemplary embodiments is given the same sign and its description is omitted.

In the present exemplary embodiment, the second wiring 12c or 12d is bent with respect to the straight line connecting the first via 21 and the second via 22. That is to say, the second wiring 12c or 12d has an arbitrary shape connecting the first via 21 and the second via 22 except a straight line.

As shown in FIG. 14A, the second wiring 12c in the wiring board 120 has a meander shape. Here, the meander shape includes a wave shape expressed by a curved line, a rectangular wave shape or the like. The wiring board 120 has the same structure as that of the first exemplary embodiment shown in FIG. 1 except for the second wiring 12c.

As shown in FIG. 15A, the second wiring 12d in the wiring board 130 has a spiral shape. Here, the spiral shape includes a spiral expressed by a curved line, a spiral having a corner, or the like. The wiring board 130 has the same structure as that of the first exemplary embodiment shown in FIG. 1 except for the second wiring 12d.

(The Function of the Wiring Boards 120 and 130)

With respect to the second wiring 12c or 12d in the present exemplary embodiment, it is possible to lengthen the wiring length of the second wiring 12c or 12d if the distance between the first via 21 and the second via 22 is constant. In other words, it is possible to shorten the distance between the first via 21 and the second via 22 keeping constant a frequency at which the noise by the second wiring 12c or 12d is removed. Accordingly, it is possible to miniaturize the wiring boards 120 and 130.

(The Effect of the Wiring Boards 120 and 130)

Since each of the wiring boards 120 and 130 to remove noise is composed of a two-layered wiring layer including the first wiring layer 10 and the second wiring layer 30, it is possible to make it thinner.

Additionally, since the second wiring 12c or 12d is bent, it is possible to miniaturize the wiring boards 120 and 130 keeping constant a frequency at which the noise is removed.

In addition, it is possible to adjust the wiring length of the second wiring 12c or 12d by using efficiently the area of the first wiring layer 10 in the wiring board 120 or 130.

### The Eighth Exemplary Embodiment

(A Structure of a Wiring Board)

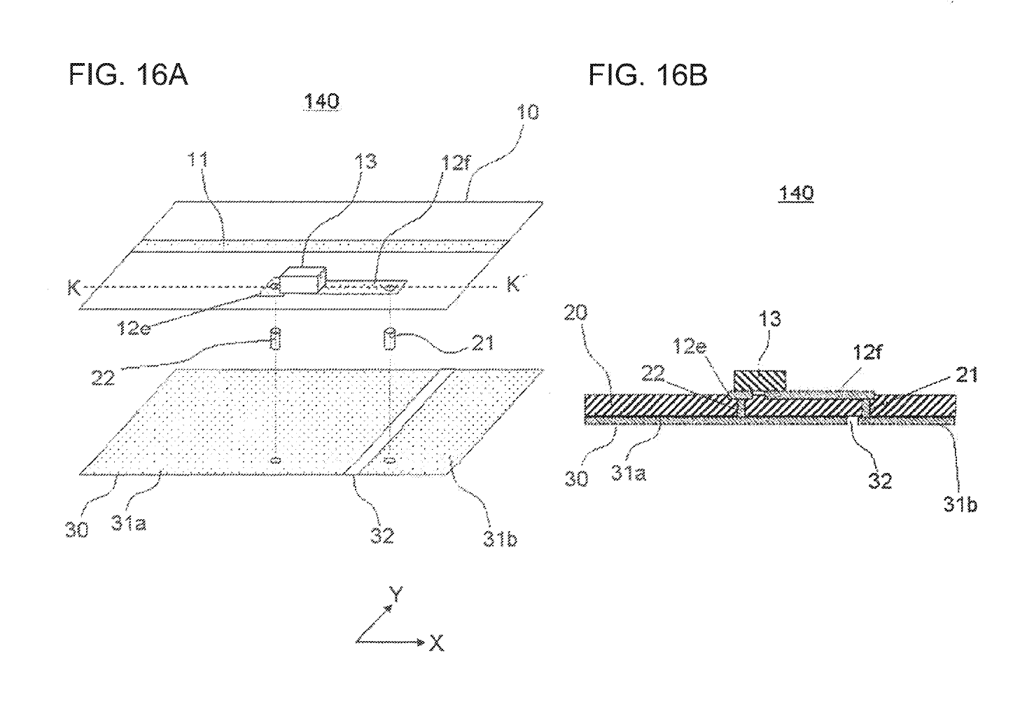

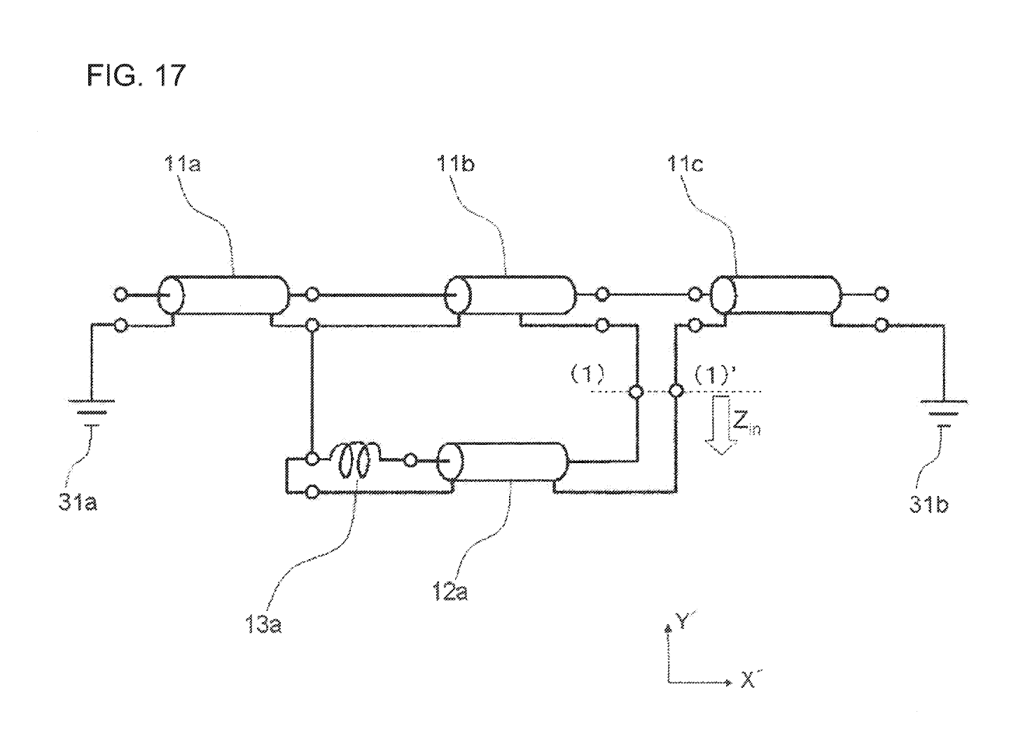

A wiring board of the eighth exemplary embodiment will be described referring to FIGS. 16A, 16B, and 17. Here, FIG. 16A is a developed view of the wiring board 140, and FIG. 16B is a cross-sectional view taken along the line K-K′ of FIG. 16A.

In the present exemplary embodiment, each configuration which has approximately the same function as that of the configuration in the first to fourth exemplary embodiments is given the same sign and its description is omitted.

In the present exemplary embodiment, a second inductor chip 13 is included, and the second wirings 12e and 12f are separated and electrically connected by means of the second inductor chip 13.

As shown in FIGS. 16A and 16B, with regard to the wiring board 140, the second wirings 12e and 12f are separated. The right end of the second wiring 12e is electrically connected to the left end of the second wiring 12f through the second inductor chip 13. The wiring board 140 has the same structure as that of the first exemplary embodiment shown in FIG. 1 except for the second wirings 12e and 12f and the second inductor chip 13.

(The Function of the Wiring Board 140)

The function of the wiring board 140 will be described referring to FIG. 17. FIG. 17 is an equivalent circuit of the wiring board 140. The equivalent circuit in FIG. 17 differs from that shown in FIG. 2 in that there is a transmission circuit model 13a of the second inductor chip. The left-hand signal terminal and the reference terminal of the transmission circuit model 12a of the second wiring are terminated by the transmission circuit model 13a of the second inductor chip.

As is the case with the first exemplary embodiment, in FIG. 17, an input impedance Zᵢₙ is defined as a value viewed from the right-hand signal terminal and the reference terminal in the transmission circuit model 12a of the second wirings (see the dotted line (1)-(1)′) toward the short-circuited part on the left side of the transmission circuit model 12a of the second wirings.

If the length of the second wiring 12e is sufficiently smaller than that of 12f, so that it can be neglected, and additionally the transmission loss of the second wirings 12e and 12f can be neglected, the input impedance Zᵢₙ is expressed by the following formula 6. Here, Z_{g} represents the characteristic impedance of the transmission circuit model 12a of the second wiring, d represents the length of the second wiring 12f, L represents the inductance value of the second inductor chip 13, and f represents a signal frequency.

$${Z}_{in} = j {Z}_{g} \frac{2 π fL + {Z}_{g} tan β d}{{Z}_{g} - 2 π fL tan β d} \qquad FORMULA 6$$

The input impedance Zᵢₙ expressed by formula 6 becomes infinite theoretically when the denominator becomes zero, that is, tan(βd) takes a value expressed by the following formula 7. At the frequency f with the denominator becoming zero, the second wirings 12e and 12f and the second inductor chip 13 function as a resonator to remove a noise, and the signal propagation is inhibited by preventing a return current on the first wiring 11 from propagating.

$$tan β d = \frac{{Z}_{g}}{2 π fL} \qquad FORMULA 7$$

Here, tan(βd) monotonically increases with βd. Therefore, if the frequency f and the characteristic impedance Z_{g} are constant, d decreases as L increases in formula 7. That is to say, if L is increased, it is possible to shorten the length of the second wiring 12f which is represented by d. In this way, by terminating the second wirings 12e and 12f by the second inductor chip 13, it is possible to miniaturize the wiring board 140.

(The Effect of the Wiring Board 140)

Since the wiring board 140 to remove noise is composed of a two-layered wiring layer including the first wiring layer 10 and the second wiring layer 30, it is possible to make it thinner.

Additionally, since the second wiring 12f is terminated by the second inductor chip 13, it is possible to miniaturize the wiring board 140.

### The Ninth Exemplary Embodiment

(A Structure of a Wiring Board)

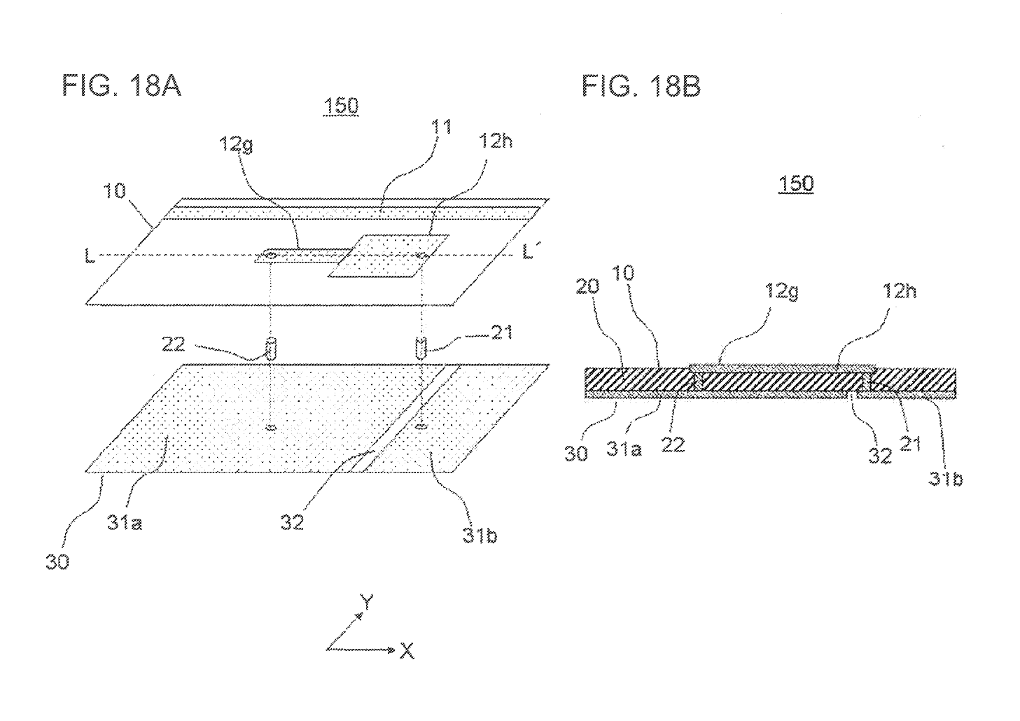

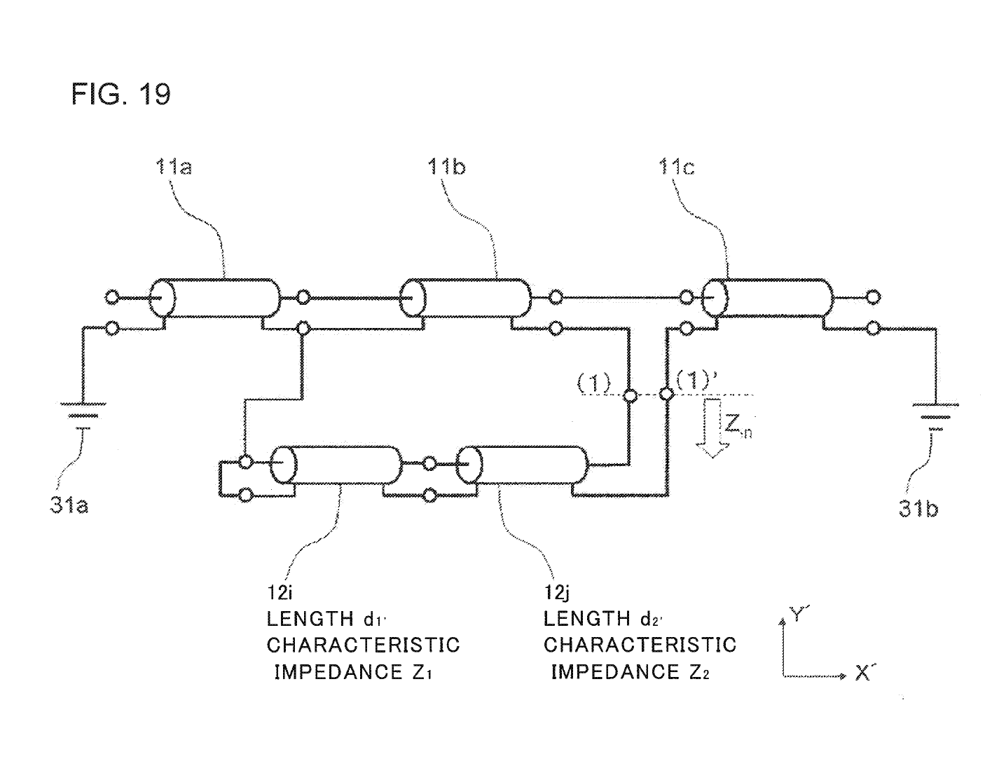

A wiring board of the ninth exemplary embodiment will be described referring to FIGS. 18A, 18B, and 19. Here, FIG. 18A is a developed view of the wiring board 150, and FIG. 18B is a cross-sectional view taken along the line L-L′ of FIG. 18A.

In the present exemplary embodiment, each configuration which has approximately the same function as that of the configuration in the first to eighth exemplary embodiments is given the same sign and its description is omitted.

In the present exemplary embodiment, second wirings 12g and 12h differ in width, whose width is a breadth in the direction approximately perpendicular to the direction corresponding to the direction connecting the first via 21 to the second via 22 in plane with the second wirings 12g and 12h.

As shown in FIGS. 18A and 18B, the wiring board 150 includes the second wirings 12g and 12h, the second wiring 12g is electrically connected to the second via 22, and the second wiring 12h to the first via 21. The second wirings 12g and 12h are approximately-rectangular, and a tapered shape and the like are also available. The width of the second wiring 12g is smaller than that of the second wiring 12h.

(The Function of the Wiring Board 150)

The function of the wiring board 150 will be described referring to FIG. 19. FIG. 19 is an equivalent circuit of the wiring board 150. The equivalent circuit of FIG. 19 differs from that shown in FIG. 2 in the following points. A transmission circuit model 12i composes a micro stripline of the second wiring 12g and the third wiring 31a, and a transmission circuit model 12j composes a microstripline of the second wiring 12h and the third wirings 31a and 31b. The length of the second wiring 12g is represented by d₁ and its characteristic impedance is represented by Z₁ The length of the second wiring 12h is represented by d₂ and its characteristic impedance is represented by Z₂.

Here, with regard to the second wiring 12g, it is important that the left-end signal terminal and the reference terminal of the transmission circuit model 12i are terminated with short circuit conditions, and that the width is smaller than that of the second wiring 12h and the characteristic impedance is higher. That is to say, the characteristic impedance Z₁ is larger than the characteristic impedance Z₂.

If the input impedance Zᵢₙ is defined as a value viewed from the right-end signal terminal and the reference terminal of the transmission circuit model 12j toward the transmission circuit models 12i and 12j of the second wiring, Zᵢₙ is expressed by the following formula 8.

$${Z}_{in} = j \frac{{Z}_{1} tan β {d}_{1} + {Z}_{2} tan β {d}_{2}}{1 - \frac{{Z}_{1}}{{Z}_{2}} tan β {d}_{1} tan β {d}_{2}} \qquad FORMULA 8$$

When the denominator is equal to zero, that is, the following equation in formula 9 is true, the input impedance Zᵢₙ becomes infinite.

$$tan β {d}_{1} tan β {d}_{2} = \frac{{Z}_{2}}{{Z}_{1}} \qquad FORMULA 9$$

At the frequency with the denominator becoming zero, the second wirings 12g and 12h function as a resonator to remove a noise, and the signal propagation is inhibited by preventing a return current on the first wiring 11 from propagating.

Here, as is the case with formula 7 in the eighth exemplary embodiment, if the characteristic impedance Zᵢ is increased, it is possible to shorten the lengths of d₁, d₂ or d₁ and d₂ in the second wirings 12g and 12h.

In this way, by narrowing the width on the side of the characteristic impedance Z₁ varying the widths of the second wirings 12g and 12h, the length of the second wirings 12g and 12h becomes shorter for the same resonant frequency, and accordingly it is possible to miniaturize the wiring board 150.

The side on which to be terminated with short circuit conditions in the equivalent circuit is a side corresponding to a distant one of the distance from the non-wiring portion 32 to the first via 21 and the distance from the non-wiring portion 32 to the second via 22 on the second wiring layer 30.

In FIGS. 18A and 18B, since the distance between the second via 22 and the non-wiring portion 32 is farther than the distance between the second via 21 and the non-wiring portion 31, terminals on the side of the second via 22 are terminated with short circuit conditions in the equivalent circuit as shown in FIG. 19. Accordingly, with regard to the wiring board 150, the second wiring 12g is small in width which is electrically connected to the second via 22.

(The Effect of the Wiring Board 150)

Since the wiring board 150 to remove noise is composed of a two-layered wiring layer including the first wiring layer 10 and the second wiring layer 30, it is possible to make it thinner.

By varying the widths of the second wirings 12g and 12h, the length of the second wirings 12g and 12h becomes shorter for the same resonant frequency, and accordingly it is possible to miniaturize the wiring board 150.

### The Tenth Exemplary Embodiment

(A Structure of a Wiring Board)

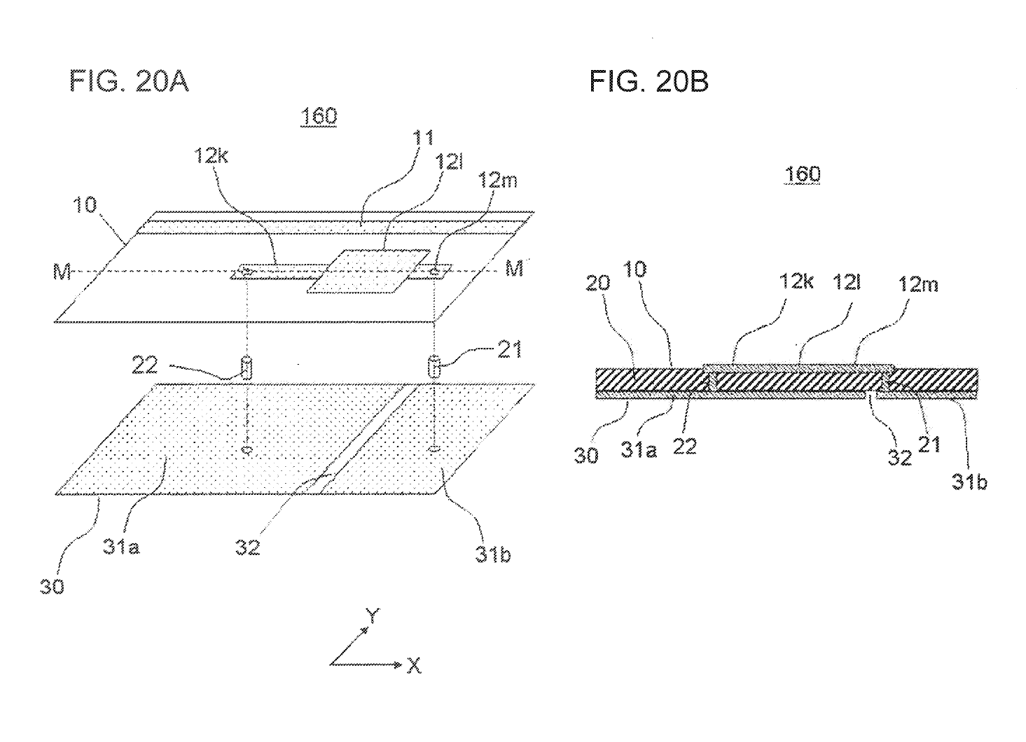

The tenth exemplary embodiment will be described referring to FIGS. 20A and 20B. Here, FIG. 20A is a developed view of the wiring board 160, and FIG. 20B is a cross-sectional view taken along the line M-M′ of FIG. 20A.

In the present exemplary embodiment, the structure of the third exemplary embodiment is incorporated into the ninth exemplary embodiment. Second wirings 12k, 12l, and 12m are approximately-rectangular. The width of the second wiring 12k is narrower than that of the second wiring 121 and is equal to that of the second wiring 12m.

As is the case with the third exemplary embodiment, the first via 21 and the second via 22 are arranged away from the non-wiring portion 32 to the extent that noise is attenuated at the two frequencies mentioned above in the third exemplary embodiment. The second wiring 12k is electrically connected to the second via 22, and the second wiring 12m to the first via 21. In the structure, a resonator is formed on each side of the non-wiring portion 32, and it is possible to attenuate the noise at arbitrary two different frequencies.

Here, as is the case with the ninth exemplary embodiment, because the second wirings 12k and 12m are smaller in width than the second wiring 121, its length becomes shorter. As a result, it is possible to miniaturize the wiring board 160.

(The Effect of the Wiring Board 160)

Since the wiring board 160 to remove noise is composed of a two-layered wiring layer including the first wiring layer 10 and the second wiring layer 30, it is possible to make it thinner. Additionally, by varying the widths of the second wirings 12k, 12l, and 12m, the length of the second wirings 12k and 12m becomes shorter for the same resonant frequency, and accordingly it is possible to miniaturize the wiring board 160.

In addition, it is possible to attenuate the noise at arbitrary two different frequencies according to the wiring board 160.

The present invention has been described above referring to the exemplary embodiments, but the present invention is not limited to the above-described exemplary embodiments. To the configurations and details of the present invention, various changes which are to be understood by those skilled in the art may be made within the scope of the present invention.

The whole or part of the exemplary embodiments disclosed above can be described as, but not limited to, the following supplementary notes.

(Supplementary note 1) A wiring board, comprising:a first wiring layer, an intermediate layer, and a second wiring layer; wherein the second wiring layer, the intermediate layer, and the first wiring layer are stacked in this order; the first wiring layer comprises a first wiring and a second wiring separated from the first wiring; the intermediate layer comprises a first via and a second via; the second wiring layer comprises a third wiring and a non-wiring portion where wirings are not formed; the first wiring is separated from the third wiring; the first via and the second via electrically connect the second wiring to the third wiring respectively; the non-wiring portion is located at a portion corresponding to an area between the first via and the second via; and the first wiring and the second wiring cross over the non-wiring portion.

(Supplementary note 2) The wiring board according to supplementary note 1, wherein the third wiring is separated in the direction of traverse by the non-wiring portion.

(Supplementary note 3) The wiring board according to supplementary note 1, wherein the non-wiring portion is located inside the third wiring.

(Supplementary note 4) The wiring board according to supplementary note 3, wherein the non-wiring portion comprises openings which are approximately-rectangular and extend approximately parallel to the first wiring respectively from two ends at which to intersect in the direction of traverse.

(Supplementary note 5) The wiring board according to supplementary note 2, further comprising: a first inductor chip; wherein the third wirings separated from each other are electrically connected by the first inductor chip respectively.

(Supplementary note 6) The wiring board according to any one of supplementary notes 1, 2, 3, 4, and 5, wherein the second wiring is bent with respect to a straight line connecting the first via and the second via.

(Supplementary note 7) The wiring board according to supplementary note 6, wherein the second wiring has one of a meander shape and a spiral shape.

(Supplementary note 8) The wiring board according to any one of supplementary notes 1, 2, 3, 4, 5, 6, and 7, further comprising: a second inductor chip; wherein the second wiring is separated and electrically connected by means of the second inductor chip.

(Supplementary note 9) The wiring board according to any one of supplementary notes 1, 2, 3, 4, 5, 6, 7, and 8, wherein the second wiring differs in width, whose width is a breadth in the direction approximately perpendicular to the direction corresponding to the direction connecting the first via to the second via in plane with the second wiring.

(Supplementary note 10) The wiring board according to any one of supplementary notes 1, 2, 3, 4, 5, 6, 7, 8, and 9, wherein the first wiring is one of a signal wiring and a power supply wiring, and the second wiring and the third wiring are ground wirings.

(Supplementary note 11) An wiring board mounting integrated-circuits, comprising: a first wiring layer, an intermediate layer, a second wiring layer, and a first and a second integrated circuit, wherein the layers are stacked in the order of the second wiring layer, the intermediate layer and the first wiring layer; the first wiring layer comprises a first wiring and a second wiring separated from the first wiring; the intermediate layer comprises a first and a second via; the second wiring layer comprises a third wiring and a non-wiring portion with no wiring provided; the first wiring is separated from the third wiring; the first and second vias each electrically connect the second wiring with the third wiring; the non-wiring portion is located at a portion corresponding to that between the first and second vias; the first and second wirings cross over the non-wiring portion; the first integrated circuit is electrically connected to one end of the first wiring; and the second integrated circuit is electrically connected to the other end of the first wiring.

This application is based upon and claims the benefit of priority from Japanese Patent Application No. 2011-196934, filed on Sep. 9, 2011, the disclosure of which is incorporated herein in its entirety by reference.

### DESCRIPTION OF THE CODES

1, 1a, 40, 60, 70, 80, 90, 100, 110, 120, 130, 140, 150, 160 wiring board

10 first wiring layer

11 first wiring

11a, 11b, 11c transmission circuit model of first wiring

12, 12b, 12c, 12d, 12e, 12f, 12g, 12h, 12k, 12l, 12m second wiring

12a, 12i, 12j transmission circuit model of second wiring

13 second inductor chip

13a transmission circuit model of second inductor chip

20 intermediate layer

21, 21a, 21b, 21c first via

22, 22a, 22b, 22c second via

23 third via

30 second wiring layer

31, 31a, 31b third wiring

32, 32a, 32b non-wiring portion

33a, 33b, 33c, 33d opening

34 first inductor chip

35, 36 pad for mounting first inductor chip

50 wiring board mounting integrated-circuits

51, 52, 53, 54 integrated circuit

55 fourth wiring

56 noise

71 inductor

71a transmission circuit model of inductor

1. A wiring board, comprising:
a first wiring layer, an intermediate layer, and a second wiring layer;
wherein the second wiring layer, the intermediate layer, and the first wiring layer are stacked in this order;
the first wiring layer comprises a first wiring and a second wiring separated from the first wiring;
the intermediate layer comprises a first via and a second via;
the second wiring layer comprises a third wiring and a non-wiring portion where wirings are not formed;
the first wiring is separated from the third wiring;
the first via and the second via electrically connect the second wiring to the third wiring respectively;
the non-wiring portion is located at a portion corresponding to an area between the first via and the second via; and
the first wiring and the second wiring cross over the non-wiring portion.

2. The wiring board according to claim 1,
wherein the third wiring is separated in the direction of traverse by the non-wiring portion.

3. The wiring board according to claim 1,
wherein the non-wiring portion is located inside the third wiring.

4. The wiring board according to claim 3,
wherein the non-wiring portion comprises openings which are approximately-rectangular and extend approximately parallel to the first wiring respectively from two ends at which to intersect in the direction of traverse.

5. The wiring board according to claim 2, further comprising:
a first inductor chip;
wherein the third wirings separated from each other are electrically connected by the first inductor chip respectively.

6. The wiring board according to claim 1
wherein the second wiring is bent with respect to a straight line connecting the first via and the second via.

7. The wiring board according to claim 6,
wherein the second wiring has one of a meander shape and a spiral shape.

8. The wiring board according to claim 1 further comprising:
a second inductor chip;
wherein the second wiring is separated and electrically connected by means of the second inductor chip.

9. The wiring board according to claim 1
wherein the second wiring differs in width, whose width is a breadth in the direction approximately perpendicular to the direction corresponding to the direction connecting the first via to the second via in plane with the second wiring.

10. The wiring board according to claim 1
wherein the first wiring is one of a signal wiring and a power supply wiring, and the second wiring and the third wiring are ground wirings.

11. The wiring board according to claim 2,
wherein the second wiring is bent with respect to a straight line connecting the first via and the second via.

12. The wiring board according to claim 3,
wherein the second wiring is bent with respect to a straight line connecting the first via and the second via.

13. The wiring board according to claim 4,
wherein the second wiring is bent with respect to a straight line connecting the first via and the second via.

14. The wiring board according to claim 5,
wherein the second wiring is bent with respect to a straight line connecting the first via and the second via.

15. The wiring board according to claim 2, further comprising:
a second inductor chip;
wherein the second wiring is separated and electrically connected by means of the second inductor chip.

16. The wiring board according to claim 3, further comprising:
a second inductor chip;
wherein the second wiring is separated and electrically connected by means of the second inductor chip.

17. The wiring board according to claim 4, further comprising:
a second inductor chip;
wherein the second wiring is separated and electrically connected by means of the second inductor chip.

18. The wiring board according to claim 5, further comprising:
a second inductor chip;
wherein the second wiring is separated and electrically connected by means of the second inductor chip.

19. The wiring board according to claim 2,
wherein the second wiring differs in width, whose width is a breadth in the direction approximately perpendicular to the direction corresponding to the direction connecting the first via to the second via in plane with the second wiring.

20. The wiring board according to claim 3,
wherein the second wiring differs in width, whose width is a breadth in the direction approximately perpendicular to the direction corresponding to the direction connecting the first via to the second via in plane with the second wiring.
